(19) United States
(12) Patent Application Publication
(10) Pub. No.: US 2011/0266616 A1
(43) Pub. Date: Nov. 3, 2011

(54) TRENCHED POWER SEMICONDUCTOR STRUCTURE WITH REDUCED GATE IMPEDANCE AND FABRICATION METHOD THEREOF

(76) Inventor: Hsiu Wen HSU, Hsinchu County (TW)

(21) Appl. No.: 12/768,922

(22) Filed: Apr. 28, 2010

(51) Int. Cl. H01L 29/49; H01L 21/336; H01L 29/78; H01L 21/28

(52) U.S. Cl. 257/330; 438/589; 438/270; 257/E21.195; 257/E21.41; 257/E29.15; 257/E29.262

(57) ABSTRACT

A trenched power semiconductor structure with reduced gate impedance and a fabrication method thereof is provided. The trenched power semiconductor structure has a silicon base, a gate trench, a gate oxide layer, and a gate polysilicon structure. The gate trench is formed in the silicon base and extended to an upper surface of the silicon base. The gate oxide layer is formed at least on the inner surface of the gate trench. The gate polysilicon structure is formed in the gate trench with a protruding portion extended form the upper surface of the semiconductor substrate upward. A concave is formed on a sidewall of the protruding portion to expose the upper surface of the silicon base adjacent to the gate trench.

### BACKGROUND OF THE INVENTION

1. Field of the Invention

This invention relates to a trenched power semiconductor structure and more particularly relates to a trenched power semiconductor structure with low gate impedance.

2. Description of the Prior Art

It is a typical method to reduce the width and depth of the gate trench so as to achieve the object of increasing cell density of the trenched power semiconductor structure. However, the shrinkage of cross section area of the polysilicon gate within the trench may result in the increasing of gate impedance, which may affect switching speed of the power semiconductor structure and result in the increasing of switching loss.

FIGS. 1A and 1B are schematic views showing a typical fabrication method of a trenched power semiconductor structure. Firstly, as shown in FIG. 1A, a gate trench 130 is formed in a silicon substrate 110. Then, a gate oxide layer 140 is formed to line the inner surfaces of the gate trench 130. Afterward, as shown in FIG. 1B, a polysilicon film is deposited on the silicon substrate 110 and then an etching back step is carried out to remove the unwanted portion and leave a polysilicon gate 150 in the gate trench 130. The upper surface of the polysilicon gate 150 is located within the gate trench 130 and is kept away from the upper surface of the silicon substrate 110 with a predetermined distance. Then, a dielectric structure 160 is formed on the polysilicon gate 150 to electrically separate the polysilicon gate 150 from the source metal layer (not shown), which will be fabricated in the following steps.

The size of the cross section area of the polysilicon gate 150 is restricted by the width and depth of the gate trench 130. The shrinkage of trench width may lead to high gate impedance to hinder the increasing of switching speed of the power semiconductor structure. To resolve this problem, a typical method is to let the polysilicon gate 150 protruding the gate trench 130 to increase the cross section area and keep the narrow gate trench.

FIGS. 2A to 2D are schematic views showing a typical fabrication method of a trenched power semiconductor structure with low gate impedance. The fabrication method uses a hard mask 224 to replace the traditional photoresist layer to define the gate trench. The thickness of hard mask 224 is much smaller than that of the photoresist layer, which is about 0.5 to 1 micron. Thus, the usage of hard mask 224 is helpful for reducing the aspect ratio of etching pattern during the etching step.

As shown in FIG. 2A, firstly, a hard mask 224 is formed on the silicon substrate 210. The hard mask 224 with the openings 226 to define the gate trenches may be an oxide layer or a nitride layer. The openings 226 is defined by using a photoresist layer and formed by selectively etching.

Then, as shown in FIG. 2B, the gate trenches 230 are formed in the silicon substrate 210 by etching. The dashed line in this figure indicates the shape of the hard mask 224 before etching. The present etching step adopts the anisotropic etching technology, which has poor selectively etching ability and part of the hard mask 224 would be removed during the etching step. In addition, even the anisotropic etching technology cannot guarantee the immunity of lateral etching. Thus, after the etching step, the thickness of the hard mask 224 is reduced and the width of the opening 226 is widened for the existence of lateral etching. Thereafter, as shown in FIG. 2C, the gate trench 230 and the opening 226 of the hard mask 224 are filled with polysilicon material, and then an etching back process is carried out to remove the unwanted portion to leave the polysilicon gate 250. The polysilicon gate 250 has an upper edge thereof protruding the upper surface of the silicon substrate 210. Afterward, as shown in FIG. 2D, the hard mask 224 on the upper surface of the silicon substrate 210 is removed to expose the silicon substrate 210 for the following ion implantation steps.

As mentioned, the etching step of FIG. 2B results in the hard mask with an opening 226, which is apparently wider than the opening of the gate trench 230. Thus, the polysilicon gate 250 filled into the gate trench 230 and the opening 226 has a wider portion located above the silicon substrate 210, which may result in shadowing effect happens on the upper surface of the silicon substrate 210 adjacent to the polysilicon gate 250 and badly affect the following ion implantation steps.

Accordingly, how to increase the cross section area of the polysilicon gate but prevent the shadowing effect due to the protruding portion of the polysilicon gate on the silicon substrate is an urgent problem to be resolved.

### SUMMARY OF THE INVENTION

It is a main object of the present invention to provide a trenched power semiconductor structure with low gate impedance and a fabrication method thereof, which features a polysilicon gate protruding the silicon substrate but has no shadowing effect being generated.

To achieve the above mentioned object, a fabrication method of a trenched power semiconductor structure with low gate impedance is provided in accordance with an embodiment of the present invention. The fabrication method comprises the steps of: a) providing a silicon substrate; b) forming a pattern layer on an upper surface of the silicon substrate, the pattern layer has an opening for defining a gate trench; c) forming the gate trench by etching the silicon substrate through the pattern layer with the opening being widened by lateral etching; d) forming a gate dielectric layer lining at least an inner surface of the gate trench; e) forming a first polysilicon structure in the gate trench; f) forming a spacer along a sidewall of the opening; g) forming a second polysilicon structure in a space defined by the spacer; and h) removing the spacer and the pattern layer.

Another fabrication method is provided in accordance with an embodiment of the present invention, which comprises the steps of: a) providing a silicon substrate; b) forming a gate trench in the polysilicon substrate; c) forming an oxide layer covering an exposed surface of the silicon substrate; d) forming a polysilicon structure in the gate trench; e) forming a protection layer structure in the gate trench and covering the polysilicon structure; f) growing the oxide layer on an upper surface of the silicon substrate by oxidation to have the oxide layer downwardly extended to the polysilicon structure below the protection layer structure; and g) removing the exposed oxide layer.

According to the above mentioned fabrication method, a trenched power semiconductor structure with low gate impedance is provided. The trenched power semiconductor structure with low gate impedance comprises a silicon substrate, a gate trench, a gate oxide layer, and a polysilicon gate. Wherein, the gate trench is located in the silicon substrate and extended downward from an upper surface of the silicon substrate. The gate oxide layer is located on an inner surface of the gate trench. The polysilicon gate is located in the gate trench and has a protruding portion protruding the upper surface of the silicon substrate. The protruding portion also has a concave on a side surface thereof to expose the upper surface of the silicon substrate adjacent to the gate trench.

### BRIEF DESCRIPTION OF THE DRAWINGS

The present invention will now be specified with reference to its preferred embodiment illustrated in the drawings, in which:

FIGS. 1A and 1B are schematic views showing a fabrication method of a typical trenched power semiconductor structure.

FIGS. 2A to 2D are schematic views showing a fabrication method of a typical trenched power semiconductor structure with low gate impedance.

FIGS. 3A to 3C are schematic views showing a fabrication method of a trenched power semiconductor structure with low gate impedance in accordance with a first embodiment of the present invention.

FIGS. 4A to 4C are schematic views showing a fabrication method of a trenched power semiconductor structure with low gate impedance in accordance with a second embodiment of the present invention.

FIGS. 5A to 5E are schematic views showing a fabrication method of a trenched power semiconductor structure with low gate impedance in accordance with a third embodiment of the present invention.

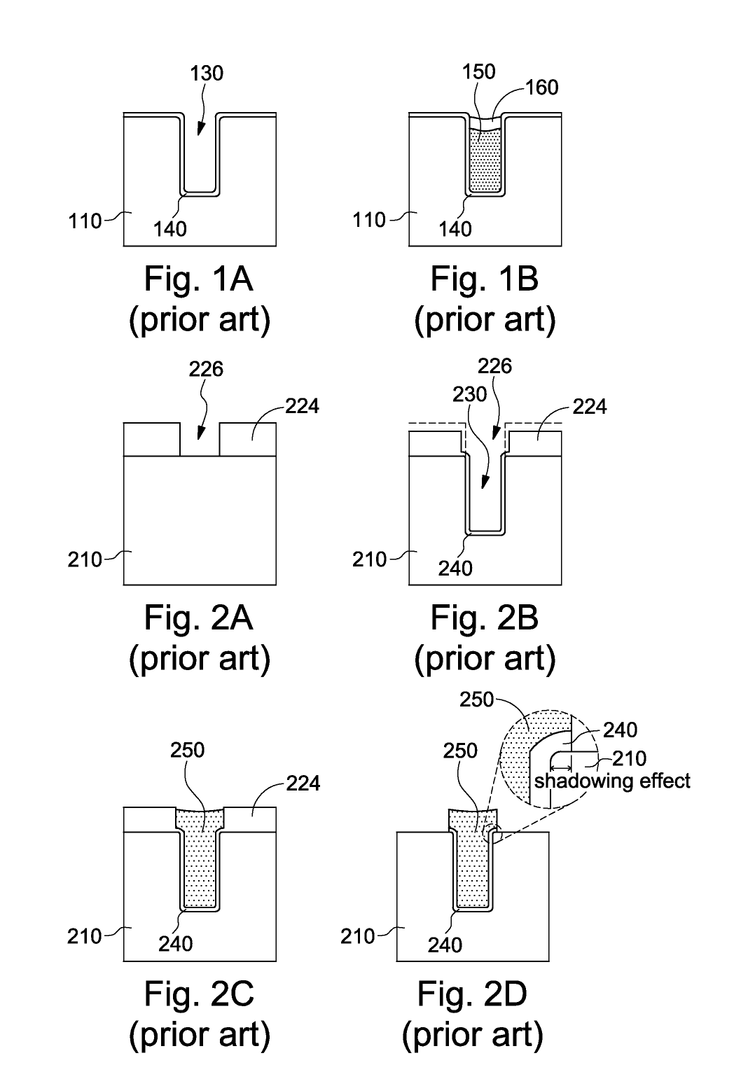

### DESCRIPTION OF THE PREFERRED EMBODIMENT

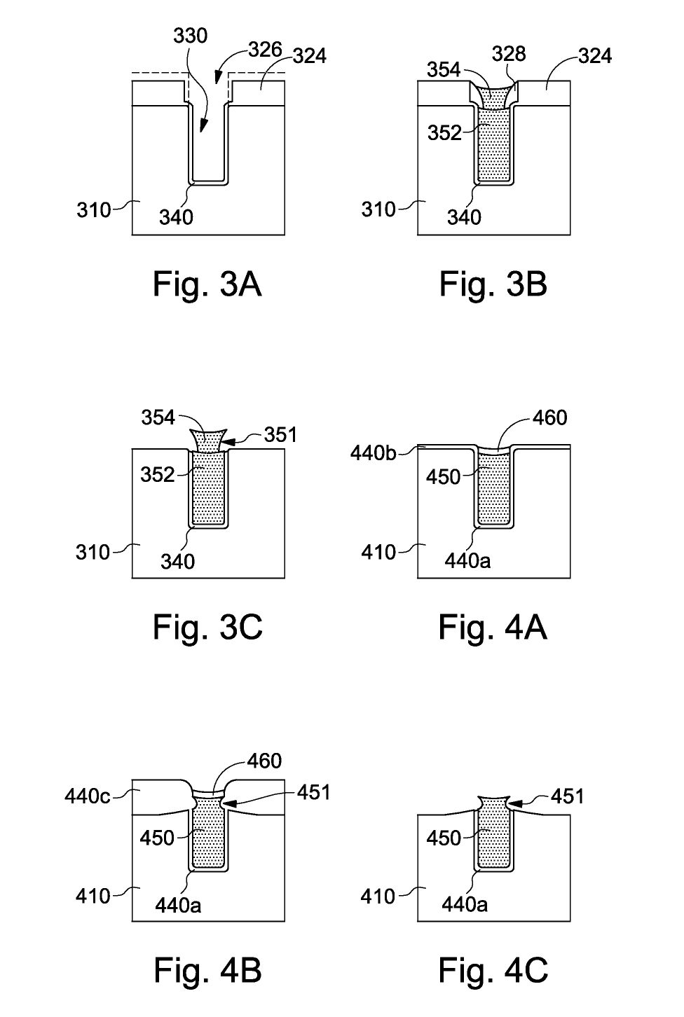

FIGS. 3A to 3C are schematic views showing a fabrication method of a trenched power semiconductor structure with low gate impedance in accordance with a first embodiment of the present invention. Firstly, as shown in FIG. 3A, a silicon substrate 310 is provided and a pattern layer 324, such as a hard mask, is formed on an upper surface of the silicon substrate 310. The pattern layer 324 has the opening 326 to define the gate trench 330.

Then, through the pattern layer 324, the gate trenched 330 is formed in the silicon substrate 310 by etching. The dashed line in this figure indicates the pattern layer 324 on the silicon substrate 310 before this etching step. As shown, the opening 326 of the pattern layer 324 is widened by lateral etching during this etching step and subsequent clean step. Afterward, a gate dielectric layer 340 is formed to cover the inner surface of the gate trench 330. Thereafter, as shown in FIG. 3B, a first polysilicon structure 352 is formed in the gate trench 330. As to the detailed fabrication process of the first polysilicon structure 352, for example, a polysilicon film is firstly deposited on the pattern layer 324 and the silicon substrate 310 and fills the gate trench 330 and the opening 326 of the pattern layer 324, and then the unwanted portion of the polysilicon film is removed by etching back to leave the first polysilicon structure 352 in the gate trench 330. It is noted that the resulted first polysilicon structure 352 is totally located in the gate trench 330. That is, the upper surface of the first polysilicon structure 352 is located below the upper surface of the silicon substrate 310.

Thereafter, as shown in FIG. 3B, a spacer 328 is formed along the side surface of the opening 326 of the pattern layer 324 to cover at least a portion of the upper surface of the first polysilicon structure 352. As to the detailed fabrication process of the spacer 328, for example, a dielectric layer is firstly formed along the side surface of the opening 326 and the upper surface of the first polysilicon structure 352 and then an anisotropic etching step followed to removed the unwanted portion of the dielectric layer so as to form the spacer 328 on the side surface of the opening 326 and to expose the first polysilicon structure 352. Thereafter, a second polysilicon structure 354 is formed in the space defined by the spacer 328 and covers the exposed surface of the first polysilicon structure 352. Finally, as shown in FIG. 3C, the spacer 328 and the pattern layer 324 are removed to expose the upper surface of the silicon substrate 310.

It is noted that the polysilicon gate, including the first polysilicon structure 352 and the second polysilicon structure 354, fabricated by using the above mentioned fabrication process has a protruding portion, the second polysilicon structure 354, protruding the upper surface of the silicon substrate 310. The protruding portion 354 has a concave 351 on a side surface thereof corresponding to the spacer 328 in FIG. 3B. The depth of the concave 351 is gradually reduced from the bottom of the protruding portion 354 upward, and the upper edge of the concave 351 is adjacent to the upper surface of the protruding portion 354. In other words, the polysilicon gate has a neck at the bottom of the protruding portion 354, and the base of the neck is substantially aligned to the upper surface of the silicon substrate 310. The concave 351 is capable to guarantee that the upper surface of the silicon substrate 310 adjacent to the gate trench 330 would not be shielded by the polysilicon gate. Thereby, shadowing effect due to the polysilicon gate 250 fabricated by using the traditional fabrication method as shown in FIG. 2D can be prevented.

FIGS. 4A to 4C are schematic views showing a fabrication method of the trenched power semiconductor structure with low gate impedance in accordance with a second embodiment of the present invention. As shown in FIG. 4A, firstly, a silicon substrate 410 is provided and then a gate trench 430 is formed in the silicon substrate 410. Afterward, an oxide layer 440a, 440b is formed to cover the exposed surfaces of the silicon substrate 410. Then, a polysilicon structure 450 is formed in the gate trench 430. As to the detailed fabrication process of the polysilicon structure 450, for example, a polysilicon film is firstly formed on the silicon substrate 410 and fills the gate trench 430 and then the unwanted portion of the polysilicon film is removed by etching back to leave the polysilicon structure 450 within the gate trench 430. It is noted that the polysilicon structure 450 is totally located in the gate trench 430 and a predetermined distance is kept between the upper surface of the polysilicon structure 450 and the upper surface of the silicon substrate 410.

Thereafter, as shown in FIG. 4A, a protection layer structure 460 is formed in the gate trench 430. The protection layer structure 460 covers the exposed surface of the polysilicon structure 450 for blocking oxygen from entering the polysilicon structure 450 to achieve the object of selectively oxidizing the silicon substrate 410. The protection layer structure 460 may be formed by silicon nitride for example. As to the fabrication process of the protection layer structure 460, for example, a protection layer is firstly formed on the silicon substrate 410 and fills the gate trench 430 and then the unwanted portion of the protection layer is removed by etching back to leave the protection layer structure 460 within the gate trench 430.

Thereafter, an oxidation step, the wet oxidation method is preferred, is carried out to let the oxide layer 440b on the upper surface of the silicon substrate 410 grow. Since the oxide layer 440a inside the gate trench 430 is substantially covered by the polysilicon structure 450 and the protection layer structure 460, only the oxide layer 440b on the upper surface of the silicon substrate 410 is exposed and grown in this oxidation step, and the thick oxide layer 440c as shown in FIG. 4B is resulted.

To make sure that the resulted oxide layer 440c is extended into the polysilicon structure 450, the thickness of the oxide layer 440c should be great enough to have the lower edge of the oxide layer 440c located below the protection layer structure 460 so that some oxygen atoms is laterally diffused to the polysilicon structure 450 below the protection layer structure 460. Finally, as shown in FIG. 4C, the exposed oxide layer 440c is removed to expose the upper surface of the silicon substrate 410.

During the step of FIG. 4A, the polysilicon structure 450 is totally located in the gate trench 430, however, after the following oxidation step as shown in FIG. 4B, the surface portion of the silicon substrate 410 is oxidized and removed to have the exposed surface of the silicon substrate 410 located below the upper surface of the polysilicon structure 450. That is, the polysilicon structure 450 formed by using the above mentioned fabrication steps also shows a protruding portion extending upward from the upper surface of the silicon substrate 410. The protruding portion has a maximum width substantially smaller than the width of the open of the gate trench 430 and has a concave 451 on a side surface thereof corresponding to the oxide layer 440c formed in the oxidation step of FIG. 4B. The lower edge of the concave 451 is aligned to the upper surface of the silicon substrate 410 to expose the upper surface of the silicon substrate 410 adjacent to the gate trench 430. In other words, the polysilicon structure 450 has a neck at the bottom of the protruding portion, and the base of the neck is substantially aligned to the upper surface of the silicon substrate 410. Thereby, shadowing effect due to the polysilicon structure 250 fabricated by using the typical method as shown in FIG. 2D can be prevented.

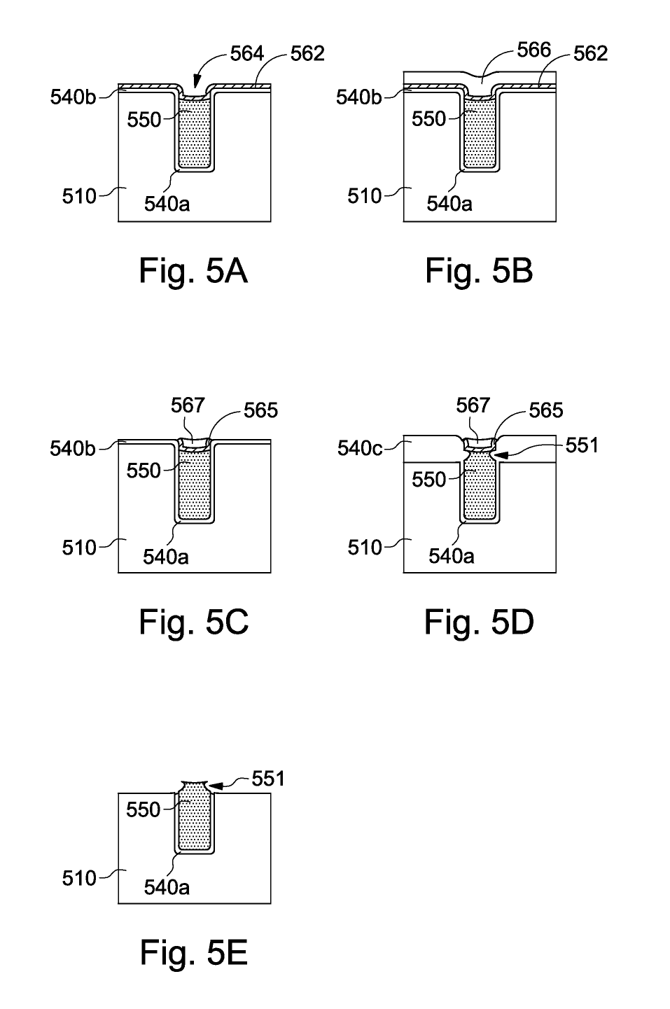

FIGS. 5A to 5E are schematic views showing a fabrication method of the trenched power semiconductor structure with low gate impedance in accordance with a third embodiment of the present invention. As shown in FIG. 5A, firstly, a silicon substrate 510 is provided and then a gate trench 530 is formed in the silicon substrate 510. Afterward, an oxide layer 540a,540b is formed to cover the exposed surfaces of the silicon substrate 510. Thereafter, a polysilicon structure 550 is formed in the gate trench 530 with a predetermined distance being kept between the upper edge thereof and the upper surface of the silicon substrate 510.

Then, in contrast with the second embodiment of the present invention, a first protection layer 562 is firstly formed along the sidewall of the gate trench 530 and the exposed surface of the polysilicon structure 550 in accordance with the present embodiment. The thickness of the first protection layer 562 is smaller than the above mentioned predetermined distance and is also smaller than half the width of the gate trench 530. Thus, a concave 564 is formed above the first protection layer 562 corresponding to the gate trench 530. Thereafter, as shown in FIG. 5B, a second protection layer 566 is formed on the first protection layer 562 to fill the gate trench 530. Basically, the thickness of the second protection layer 566 should be greater than that of the first protection layer 562.

Afterward, as shown in FIG. 5C, the portions of the first protection layer 562 and the second protection layer 566 outside the gate trench 530 is removed to expose the oxide layer 540b. As a preferred embodiment, the first protection layer 562 may be formed of silicon nitride and the second protection layer 566 may be formed of silicon oxide. As to a detailed fabrication process of the first protection structure 565, for example, the step of etching back is carried out first to remove the unwanted portion of the second protection layer 566 by using the first protection layer 562 as an etching stop layer so as to leave a second protection layer structure 567 in the concave 564. Then, the exposed first protection layer 562 is removed to leave the first protection layer structure 565 covered by the second protection layer structure 567.

As shown in FIG. 5C, after the above mentioned etching step, the oxide layer 540b on the upper surface of the silicon substrate 510 is exposed. Then, as shown in FIGS. 5D and 5E, the oxide layer 540 is grown by wet oxidation and then the resulted oxide layer 540c is removed to expose the upper surface of the silicon substrate 510.

Similar to the second embodiment of the present invention, the polysilicon structure 550 is totally located in the gate trench 530 in the step as shown in FIG. 5A, however, after the following oxidation step, the upper surface of the silicon substrate 510 is moved downward below the upper edge of the polysilicon gate 550. Thus, the resulted polysilicon gate 550 as shown in FIG. 5E also shows a protruding portion protruding the upper surface of the silicon substrate 510 and has a concave 551 on the side surface of the protruding portion corresponding to the oxide layer 540c in FIG. 5D, so as to expose the upper surface of the silicon substrate 510 adjacent to the gate trench 530. Thereby, shadowing effect due to the polysilicon gate 250 fabricated by using traditional fabrication method as shown in FIG. 2D can be prevented.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A fabrication method of a trenched power semiconductor structure of low gate impedance comprising the steps of:
a) providing a silicon substrate;
b) forming a pattern layer on an upper surface of the silicon substrate, the pattern layer has an opening for defining a gate trench;
c) forming the gate trench in the silicon substrate by etching through the pattern layer;
d) forming a gate dielectric layer lining at least an inner surface of the gate trench;
e) forming a first polysilicon structure in the gate trench;
f) forming a spacer along a sidewall of the opening of the pattern layer;
g) forming a second polysilicon structure in a space defined by the spacer; and
h) removing the spacer and the pattern layer.

2. The fabrication method of a trenched power semiconductor structure with low gate impedance of claim 1, wherein the spacer at least covers a portion of an upper surface of the first polysilicon structure.

3. A fabrication method of a trenched power semiconductor structure with low gate impedance comprising the steps of:
a) providing a silicon substrate;
b) forming a gate trench in the polysilicon substrate;
c) forming an oxide layer covering an exposed surface of the silicon substrate;
d) forming a polysilicon structure in the gate trench;
e) forming a protection layer structure in the gate trench to cover the polysilicon structure;
f) growing the oxide layer on an upper surface of the silicon substrate; and
g) removing the exposed oxide layer.

4. The fabrication method of the trenched power semiconductor structure of low gate impedance of claim 3, wherein the protection structure is formed of silicon nitride.

5. The fabrication method of the trenched power semiconductor structure of low gate impedance of claim 3, wherein the step of forming the protection layer structure comprising:
forming a first protection layer along surfaces of the silicon substrate and the polysilicon structure;
forming a second protection layer on the first protection layer to fill the gate trench; and
removing a portion of the first protection layer and the second protection layer outside the gate trench to expose the oxide layer.

6. The fabrication method of trenched power semiconductor structure with low gate impedance of claim 5, wherein the first protection layer is formed of silicon nitride.

7. The fabrication method of trenched power semiconductor structure with low gate impedance of claim 6, wherein the second protection layer is formed of silicon oxide.

8. The fabrication method of trenched power semiconductor structure with low gate impedance of claim 6, wherein a thickness of the second protection layer is greater than that of the first protection layer.

9. The fabrication method of trenched power semiconductor structure with low gate impedance of claim 3, wherein the oxide layer is grown by selectively oxidation to have the lower edge thereof downwardly extended to the polysilicon structure below the protection layer structure.

10. A trenched power semiconductor structure with low gate impedance comprising:
a silicon substrate;
a gate trench, located in the silicon substrate and extended downward from an upper surface of the silicon substrate;
a gate oxide layer, located on an inner surface of the gate trench; and
a polysilicon gate, located in the gate trench and having a protruding portion protruding the upper surface of the silicon substrate, the protruding portion having a concave on a side surface thereof to expose the upper surface of the silicon substrate adjacent to the gate trench.

11. The trenched power semiconductor structure with low gate impedance of claim 10, wherein a lower edge of the concave is aligned to the upper surface of the silicon substrate.

12. The trenched power semiconductor structure with low gate impedance of claim 10, wherein an upper edge of the concave is adjacent to an upper surface of the polysilicon gate.

13. The trenched power semiconductor structure with low gate impedance of claim 10, wherein a maximum width of the protruding portion is smaller than a width of an open of the gate trench.

14. The trenched power semiconductor structure with low gate impedance of claim 10, wherein a depth of the concave is gradually reduced from a bottom of the protruding portion upward.
